(19) United States
(12) Patent Application Publication
(10) Pub. No.: US 2024/0258241 A1
(43) Pub. Date: Aug. 1, 2024

(54) ELECTRONIC DEVICE AND MANUFACTURING METHOD THEREOF

(71) Applicant: InnoLux Corporation, Miao-Li County (TW)

(72) Inventors: Jui-Jen YUEH, Miao-Li County (TW); Cheng-Chi Wang, Miao-Li County (TW); Ju-Li Wang, Miao-Li County (TW)

(73) Assignee: InnoLux Corporation, Miao-Li County (TW)

(21) Appl. No.: 18/406,204

(22) Filed: Jan. 7, 2024

(30) Foreign Application Priority Data
Jan. 28, 2023 (CN) 202310082186.9

(51) Int. Cl. H01L 23/538; H01L 21/56; H01L 23/00

(52) U.S. Cl. CPC H01L 23/5386; H01L 21/568; H01L 24/13; H01L 24/16; H01L 24/19; H01L 24/20; H01L 23/5383; H01L 25/03; H01L 25/16; H01L 2224/13111; H01L 2224/13139; H01L 2224/13144; H01L 2224/13155; H01L 2224/16227; H01L 2224/19; H01L 2224/211

(57) ABSTRACT

The present disclosure provides an electronic device and a manufacturing method. The electronic device includes a base layer, a first redistribution structure, a first electronic unit, a second electronic unit, a protecting layer, and a connecting component. The base layer includes at least one via structure. The first redistribution structure is disposed on the base layer, and the first electronic unit and the second electronic unit are disposed on the first redistribution structure. The protecting layer surrounds the first electronic unit and the second electronic unit, and the first electronic unit and the second electronic unit are electrically connected to the connecting component through the first redistribution structure and the at least one via structure.

### BACKGROUND OF THE DISCLOSURE

### 1. Field of the Disclosure

The present disclosure relates an electronic device and a manufacturing method thereof and more particularly to an electronic device having a connecting component electrically connected to two electronic units and a manufacturing method thereof.

### 2. Description of the Prior Art

Recently, in order to integrate various functions to meet user's requirements, multiple package components with different functions are disposed on a circuit board. However, a size of entire structure is limited by sizes of the multiple package components and distances between them that is able to be shrunk by processes.

Accordingly, the entire structure cannot be further thinned or miniaturized, or signal transmission loss between package components remains high. Furthermore, because the multiple package components are easily displaced during being disposed on the circuit board, as the package components are designed to be electrically connected to each other, they need to be further compensated, resulting in manufacturing difficulty.

### SUMMARY OF THE DISCLOSURE

According to an embodiment, the present disclosure provides an electronic device including a base layer, a first redistribution structure, a first electronic unit, a second electronic unit, a protecting layer, and a connecting component. The base layer includes at least one via structure. The first redistribution structure is disposed on the base layer, and the first electronic unit and the second electronic unit are disposed on the first redistribution structure. The protecting layer surrounds the first electronic unit and the second electronic unit, and the first electronic unit and the second electronic unit are electrically connected to the connecting component through the first redistribution structure and the at least one via structure.

According to another embodiment, the present disclosure provides a manufacturing method of an electronic device. First, a base layer is formed on a carrier, in which the base layer has at least one via structure. Then, a first redistribution structure is formed on the base layer, and a first electronic unit and a second electronic unit are disposed on the first redistribution structure. Next, a protecting layer is formed on the first redistribution structure, in which the protecting layer surrounds the first electronic unit and the second electronic unit. Subsequently, the carrier is removed, in which the manufacturing method further includes forming a connecting component, and the first electronic unit and the second electronic unit are electrically connected to the connecting component through the first redistribution structure and the at least one via structure.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 schematically illustrates a top view of an electronic device according to a first embodiment of the present disclosure.

FIG. 2 is a schematic cross-sectional view taken along a line A-A′ of FIG. 1.

FIG. 3 schematically illustrates a cross-sectional view of the connecting component according to an embodiment of the present disclosure.

FIG. 4 schematically illustrates a cross-sectional view of a connecting component according to another embodiment of the present disclosure.

FIG. 5 to FIG. 8 schematically illustrate cross-sectional structures in different steps of the manufacturing method of the electronic device according to the first embodiment of the present disclosure.

FIG. 9 schematically illustrates the formation of the conductive pillars and the traces according to another embodiment of the present disclosure.

FIG. 10 schematically illustrates a cross-sectional view of an electronic device according to a second embodiment of the present disclosure.

FIG. 11 schematically illustrates a manufacturing method of an electronic device according to a second embodiment of the present disclosure.

FIG. 12 schematically illustrates a cross-sectional view of an electronic device according to a third embodiment of the present disclosure.

### DETAILED DESCRIPTION

The contents of the present disclosure will be described in detail with reference to specific embodiments and drawings. It is noted that, for purposes of illustrative clarity and being easily understood by the readers, the following drawings may be simplified schematic diagrams, and components therein may not be drawn to scale. The numbers and sizes of the components in the drawings are just illustrative and are not intended to limit the scope of the present disclosure.

Certain terms are used throughout the specification and the appended claims of the present disclosure to refer to specific components. Those skilled in the art should understand that electronic equipment manufacturers may refer to a component by different names, and this document does not intend to distinguish between components that differ in name but not function. In the following specification and claims, the terms “comprise”, “include” and “have” are open-ended fashion, so they should be interpreted as “including but not limited to . . . ”.

The ordinal numbers used in the specification and the appended claims, such as “first”, “second”, etc., are used to describe the components of the claims. It does not mean that the component has any previous ordinal numbers, nor does it represent the order of a certain component and another component, or the sequence in a manufacturing method. These ordinal numbers are just used to make a claimed component with a certain name be clearly distinguishable from another claimed component with the same name.

Spatially relative terms, such as “above”, “on”, “beneath”, “below”, “under”, “left”, “right”, “before”, “front”, “after”, “behind” and the like, used in the following embodiments just refer to the directions in the drawings and are not intended to limit the present disclosure.

In addition, when one component or layer is “on” or “above” another component or layer or is “connected to” the another component or layer, it may be understood that the component or layer is directly on the another component or layer or directly connected to the another component or layer, and alternatively, another component or layer may be between the component or layer and the another component or layer (indirectly). On the contrary, when the component or layer is “directly on” the another component or layer or is “directly connected to” the another component or layer, it may be understood that there is no intervening component or layer between the component or layer and the another component or layer. Also, the term “electrically connected” or “coupled” includes means of direct or indirect electrical connection.

As disclosed herein, the terms “approximately”, “essentially”, “about”, or “substantially” generally mean within 20%, 10%, 5%, 3%, 2%, 1%, or 0.5% of the reported numerical value or range. The quantity disclosed herein is an approximate quantity, that is, without a specific description of “approximately”, “essentially”, “about”, or “substantially”, the quantity may still include the meaning of “approximately”, “essentially”, “about”, or “substantially”.

It should be understood that according to the following embodiments, features of different embodiments may be replaced, recombined or mixed to constitute other embodiments without departing from the spirit of the present disclosure. The features of various embodiments may be mixed arbitrarily and used in different embodiments without departing from the spirit of the present disclosure or conflicting.

In the present disclosure, the length, thickness, width, diameter, height, distance, and area may be measured by using an optical microscope (OM), a scanning electron microscope (SEM) or other approaches, but not limited thereto.

Unless otherwise defined, all terms (including technical and scientific terms) used herein have the same meaning as commonly understood by those skilled in the art. It should be understood that these terms, such as those defined in commonly used dictionaries, should be interpreted as having meaning consistent with the relevant technology and the background or context of the present disclosure, and should not be interpreted in an idealized or excessively formal way, unless there is a specific definition in the embodiments of the present disclosure.

In the present disclosure, an electronic device may, for example, include a power module, semiconductor device, a package device, a display device, a light emitting device, a solar cell, a sensing device, a touch device, a tiled device, a vehicle, a high frequency device or other suitable electronic devices, but not limited thereto. The display device may, for example, be applied to a laptop, a public display, a tiled display, a vehicle display, a touch display, a television, a monitor, a smartphone, a tablet, a light source module, a lighting device or an electronic device applied to the above product, but not limited thereto. The display device may, for example, include a light emitting diode, a fluorescent material, a phosphor material, other suitable display mediums, or any combination thereof, but not limited thereto. The light emitting diode may, for example, include an organic light emitting diode (OLED), a mini light emitting diode (mini-LED), a micro light emitting diode (micro LED), a quantum dot light emitting diode (e.g., QLED or QDLED), other suitable components or any combination of components mentioned above. The light emitting device may, for example, include a backlight module or other suitable light emitting modules. The sensing device may, for example, be a sensing device used for detecting change in capacitances, light, heat, or ultrasound, but not limited thereto. The sensing device may, for example, include a biosensor, a touch sensor, a fingerprint sensor, other suitable sensors or any combination of sensors mentioned above. The high frequency device may, for example, include liquid crystal antenna, antennas of other types or other suitable high frequency devices, but not limited thereto. The tiled device may, for example, include a tiled display device or a tiled antenna device, but not limited thereto. Furthermore, the appearance of the electronic device may be rectangular, circular, polygonal, a shape with curved edges, curved or other suitable shapes, but not limited thereto. The electronic device may have peripheral systems such as a driving system, a control system, a light source system, a shelf system, etc. The electronic device may include electronic units, in which the electronic units may include a passive component and an active component, and for example include a capacitor, a resistor, an inductor, a diode, a transistor, a sensor, etc. It is noted that the electronic device of the present disclosure may be any combination of the above-mentioned devices, but not limited thereto.

The manufacturing process of the electronic device of the present disclosure may for example be applied to the wafer-level package (WLP) process or the panel-level package (PLP) process. The WLP process or the PLP process includes the chip-first process or the chip-last process, but not limited thereto. The electronic device may include the system on a chip (SoC), the system in a package (SiP), the antenna in package (AiP) or combinations of the above-mentioned device, but not limited thereto.

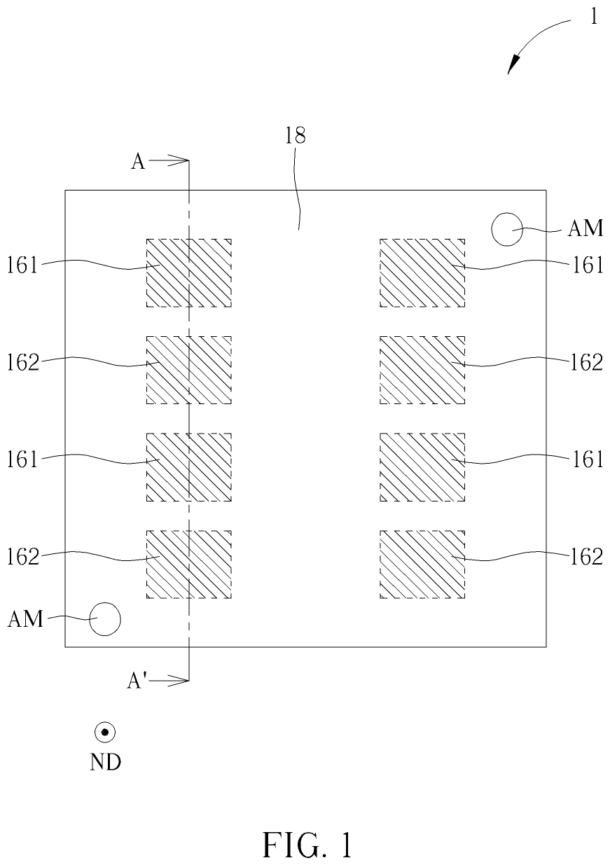

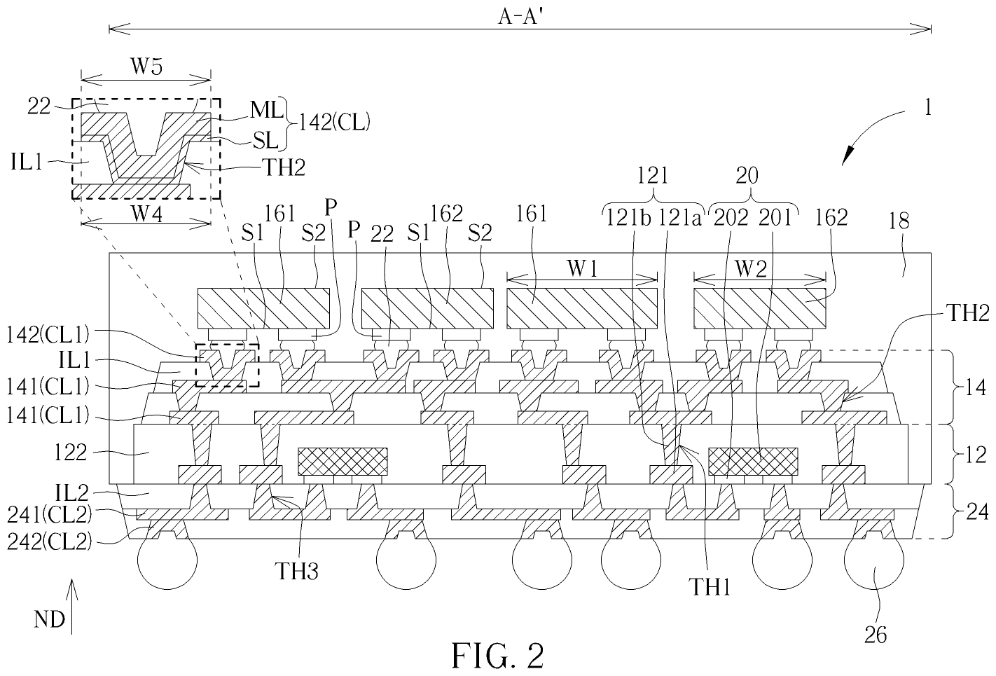

Refer to FIG. 1 and FIG. 2, FIG. 1 schematically illustrates a top view of an electronic device according to a first embodiment of the present disclosure, and for example, FIG. 2 is a schematic cross-sectional view taken along a line A-A′ of FIG. 1. As shown in FIG. 1 and FIG. 2, the electronic device 1 may include a base layer 12, a first redistribution structure 14, at least one first electronic unit 161, at least one second electronic unit 162, a protecting layer 18, and a connecting component 20. The base layer 12 may include at least one via structure 121. The first redistribution structure 14 may be disposed on the base layer 12, and the first electronic unit 161 and the second electronic unit 162 may be disposed on the first redistribution structure 14. The protecting layer 18 may surround the first electronic unit 161, the second electronic unit 162 and the base layer 12, and at least one of the first electronic unit 161 and the second electronic unit 162 is electrically connected to the connecting component 20 through the first redistribution structure 14 and the via structure 121. It should be noted that, by surrounding the first electronic unit 161 and the second electronic unit 162 through the protecting layer 18, the first electronic unit 161 and the second electronic unit 162 may be packaged in the same package module, such that the electronic device 1 may be thinned or miniaturized, or the signal transmission loss between the first electronic unit 161 and the second electronic unit 162 may be further reduced. Also, since the first electronic unit 161 and the second electronic unit 162 may be electrically connected to the same connecting component 20, the quality of electrical connections between the electronic units or reliability of the electronic device 1 may be improved by the connecting component 20, or switching between the electronic units or controls of the electronic units may be achieved by the connecting component 20, so as to have effects of switching functions or enhancing functions, such as signal conversion, enhancement of computing capacity, and/or conversion between direct current (DC) signal and alternating current (AC) signal. For example, the connecting component 20 may be another redistribution structure, an active component, a passive component or an electronic unit, but not limited thereto. The active component may include a thin film transistor, and/or the passive component may include an integrated passive device (IPD), but not limited thereto.

In FIG. 1 and FIG. 2, the electronic device 1 may include a plurality of first electronic units 161 and a plurality of second electronic units 162, in which one of the first electronic units 161 may be electrically connected in a one-to-one correspondence with one of the second electronic units 162, and this first electronic unit 161 and this second electronic unit 162 are electrically connected to the same connecting component 20, but not limited thereto. In some embodiments, a plurality of the first electronic units 161 may be electrically connected to at least one second electronic unit 162, and they are electrically connected to the same connecting component 20. For example, the first electronic units 161 may be electrically connected to the second electronic units 162 in a two-to-one correspondence, three-to-one correspondence, four-to-one correspondence, or two-to-two correspondence.

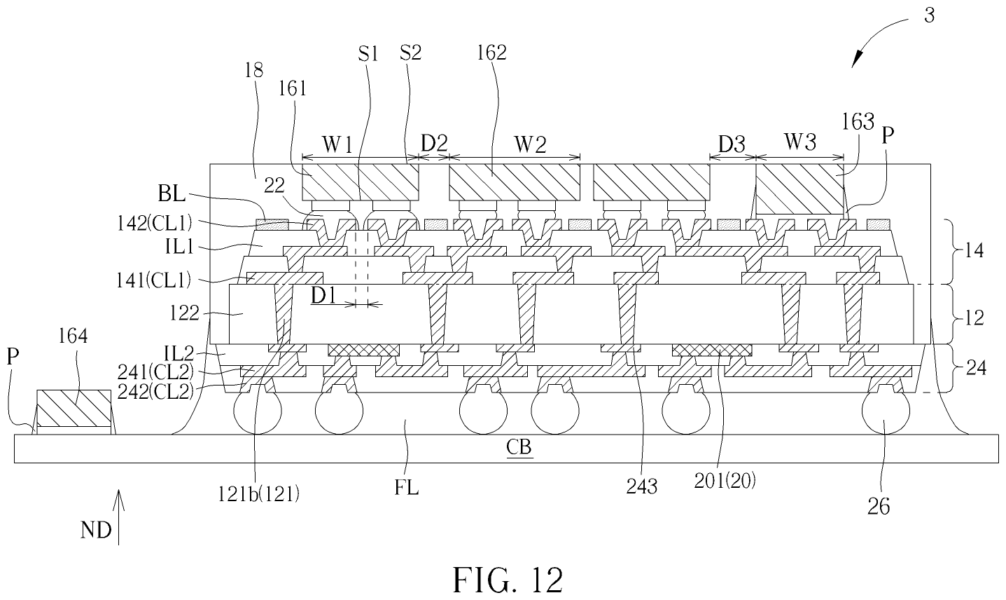

It should be noted that in some applications of the electronic device 1, such as in-vehicle application, artificial intelligence (AI), edge computing of database or other high-end applications, since they needs complex functions, electronic units in these electronic devices are not allowed to fail. In this embodiment, the second electronic unit 162 may be the same as the first electronic unit 161 or have the same function as the first electronic unit 161. In this case, the second electronic unit 162 may, for example, serve as a redundant unit or backup unit of the corresponding first electronic unit 161, so that when the first electronic unit 161 fails, the second electronic unit 162 may be used to prevent the failure of the electronic device 1, for example by the switching of the connecting component 20. Alternatively, the second electronic unit 162 may serve as a function enhancement unit. That is, when the electronic device 1 needs to produce the highest performance, the first electronic unit 161 and the corresponding second electronic unit 162 may be turned on simultaneously through the connecting component 20 to achieve maximum performance. When the electronic device 1 needs to enter a power saving mode, the connecting component 20 may turn on the first electronic unit 161 and turn off the second electronic unit 162 to achieve the effect of saving power. In some embodiments, the second electronic unit 162 and the first electronic unit 161 may have different functions, so that the electronic device 1 may have different functions. In some embodiments, the electronic device 1 may further include at least one third electronic unit 163, as shown in FIG. 12, wherein the pads P of the third electronic unit 163 may be on side surfaces of a main body of the third electronic unit 163. In some embodiments, the third electronic unit 163, the second electronic unit 162 and the first electronic unit 161 may have same or different functions. For example, a width W1 of the first electronic unit 161 is different from a width W2 of the second electronic unit 162. For example, a width W3 of the third electronic unit 163 is different from the width W1 of the first electronic unit 161 or the width W2 of the second electronic unit 162. For example, the widths W1, W2, W3 mentioned herein are measured along a direction perpendicular to the normal direction ND.

In some embodiments, the first electronic unit 161, the second electronic unit 162 and/or the third electronic unit 163 may be, for example, a chip (or die), a chip scale package (CSP) component, a circuit component or other suitable types of components. The first electronic unit 161, the second electronic unit 162 and/or the third electronic unit 163 may include, for example, an integrated circuit (IC), a memory package unit, a capacitor, a sensing component, an antenna component, an optical fiber, a circuit component, a surface mount device (SMD), a compensation circuit and/or other suitable components. In FIG. 2, each of the first electronic unit 161 and the second electronic unit 162 may have an active surface S1 and a back surface S2 opposite to each other and may include pads P disposed on the active surface S1, but not limited thereto. According to some embodiments, the electronic unit may further include a substrate. In detail, a circuit or compensation circuit may be a circuit component or a compensation circuit component on the substrate. The substrate may include a transparent or opaque organic material or a transparent or opaque inorganic material and may include a rigid or flexible material. The organic material may include, for example, polyimide (PI), polycarbonate (PC), polyethylene terephthalate (PET), liquid crystal polymer (LCP), other known suitable materials or combinations thereof, but the present disclosure is not limited thereto. The inorganic material may include a dielectric material or a metal material, but the present disclosure is not limited thereto. The rigid material may include, for example, glass, quartz, sapphire, ceramic or plastic, or other suitable materials. The “flexible material” mentioned herein refers to a material that may be curved, bent, fold, rolled, flexed, stretched and/or other similar deformations to exhibit at least one above-mentioned possible deforming manner. Examples of the flexible material may include one of the above-mentioned organic materials. The flexible material of the present disclosure is not limited to the material mentioned above, and the “flexible” is not limited to the above-mentioned deforming manner.

In the embodiment of FIG. 2, the base layer 12 may surround the connecting component 20 so as to protect the connecting component 20. For example, the connecting component 20 may be disposed in or embedded in the base layer 12. As mentioned herein, one component “surrounds” another component may refer to at least a portion of the component (e.g., the connecting component 20) may be disposed within the another component (e.g., the base layer 12) in a top view of the electronic device 1, and the another component may further contact a side surface of the component. In some embodiments, the connecting component 20 may be disposed in a recess of the base layer 12. When the recess is adjacent to the first redistribution structure 14, the first electronic unit 161 and the corresponding second electronic unit 162 may be electrically connected to the connecting component 20 through the first redistribution structure 14. For example, the redistribution structure (e.g., a redistribution layer (RDL)) may be used to redistribute the wires and/or increase the fan-out area of the wires, or the redistribution structure may function as a circuit board/substrate such that the electronic units may be electrically connected to each other through the redistribution structure.

The base layer 12 may further include an insulating body 122, and the via structure 121 may penetrate through the insulating body 122 to electrically connect components (e.g., the first redistribution structure 14 and a second redistribution structure 24 mentioned below) located on two opposite sides of the insulating body 122 to each other. The material of the insulating body 122 may include, for example, quartz, glass, epoxy resin, epoxy molding compound (EMC), other suitable packaging materials or any combination thereof, but not limited thereto. A dielectric loss (Df) of the body 122 is less than 0.1 at 10 GHz (Df<0.1 at 10 GHz). According to some embodiments, in a cross-sectional schematic diagram, a profile of the via structure 121 may include a column, a rectangle, a square, a trapezoid, or an inverted trapezoid, or may have a stepped profile, but not limited thereto. The via structure 121 of this embodiment may include a connecting pad 121a and a conductive pillar 121b stacked in sequence, wherein the insulating body 122 may have a through hole TH1 located on the connecting pad 121a, and the conductive pillar 121b is disposed in the through hole TH1, but not limited thereto. In some embodiments, the via structure 121 may not include the connecting pad 121a, so the conductive pillar 121b may penetrate through the insulating body 122, but not limited thereto. In some embodiments, as shown in FIG. 6, when the via structure 121 has a stepped profile, the conductive pillar 121b may have a stepped profile, for example. In this case, the through hole TH1 may be formed by at least two patterning processes to avoid incomplete removal caused by one patterning process. The incomplete removal may be, for example, a portion of the insulating body 122 remaining at the bottom of the through hole TH1, which affects electrical connection with components (e.g., the second redistribution structure) disposed on the base layer 12 opposite to the first redistribution structure 14. The patterning process may include, for example, a laser drilling process, an exposure process combined with a development process, an etching process or other suitable processes.

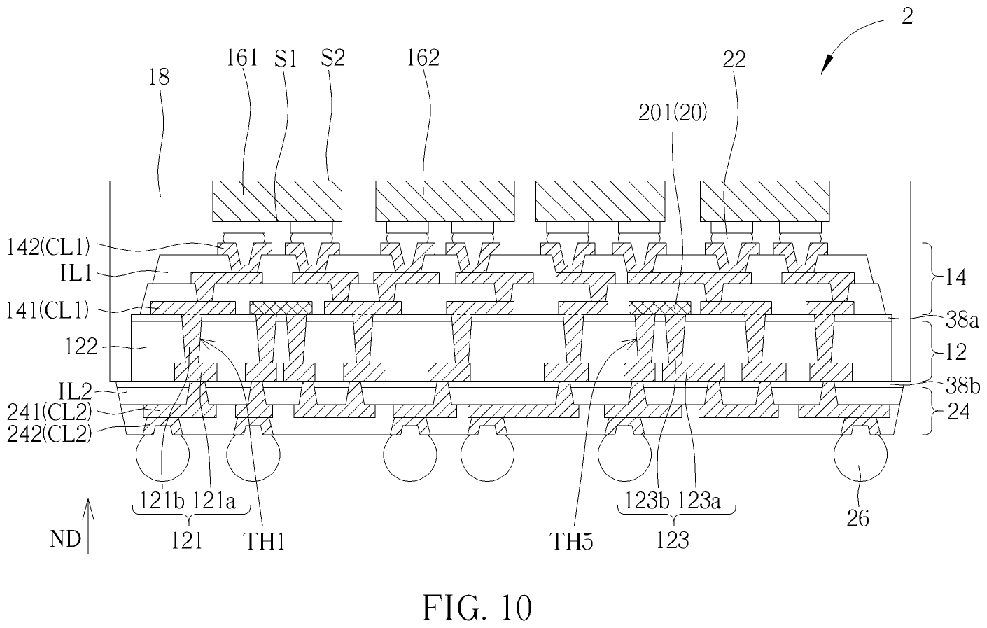

In some embodiments, the electronic device 1 may include a buffer layer disposed between the base layer 12 and the redistribution structure. That is to say, there is a first buffer layer 38a between the base layer 12 and the first redistribution structure 14, and/or there is a second buffer layer 38b between the base layer 12 and the second redistribution structure 24, for example as shown in FIG. 10. The buffer layer (e.g., the first buffer layer 38a and/or the buffer layer 38b) may balance the stress of the electronic device 1 to reduce the warpage of the electronic device 1. A coefficient of thermal expansion of the buffer layer may be greater than or equal to 1 ppm/° C. and less than or equal to 15 ppm/° C. The buffer layer may include silicon nitride, silicon oxide, silicon oxynitride, aluminum oxide, other suitable insulating materials, or any combination thereof, but not limited thereto. A thickness of the buffer layer may be ranged from about 500 nanometers (nm) to about 3000 nm (i.e., 500 nm≤the thickness of the buffer layer≤3000 nm).

In some embodiments, the insulating body 122 may include a plurality of first filling particles distributed in the insulating body 122, so that the base layer 12 may have a supporting property and be used to carry components formed thereon. The first filling particles may, for example, include silicon dioxide or other suitable materials. A particle size of the first filling particle of the insulating body 122 may be, for example, ranged from 0.5 micrometers (μm) to 10 μm (i.e., 0.5 μm≤the particle size of the first filling particle≤10 μm), such that the through hole TH1 with good quality may be formed during forming the through hole TH1 in the insulating body 122, but not limited thereto.

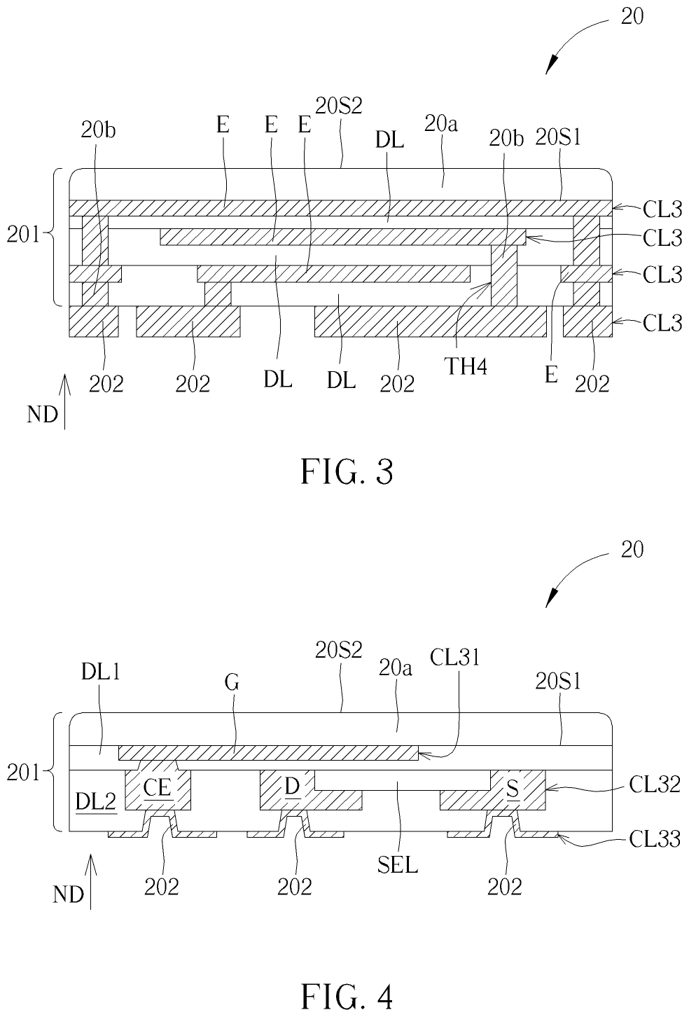

In the embodiment of FIG. 2, the connecting component 20 may include a component body 201 and a plurality of connecting pads 202, and the component body 201 may be disposed between the connecting pads 202 and the insulating body 122, such that the connecting pads 202 may be exposed from a lower side of the base layer 12. The connecting component 20 may include, for example, the IC, the glass IC, the IPD, the antenna component, another redistribution structure, the passive component, or other suitable components. Exemplars of specific structure of the connecting component 20 may refer to FIG. 3 or FIG. 4 and the relevant description mentioned below.

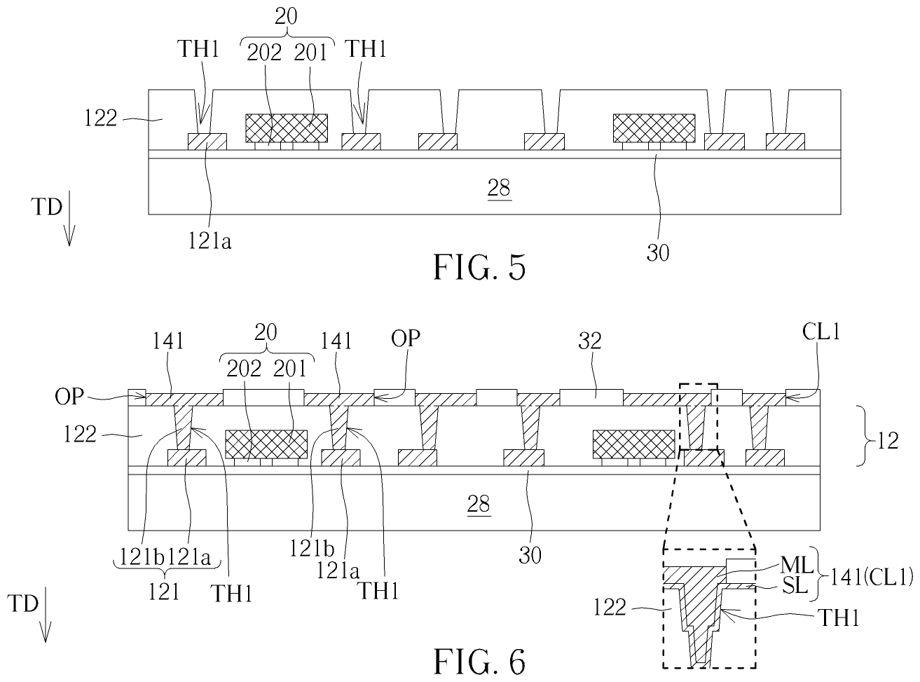

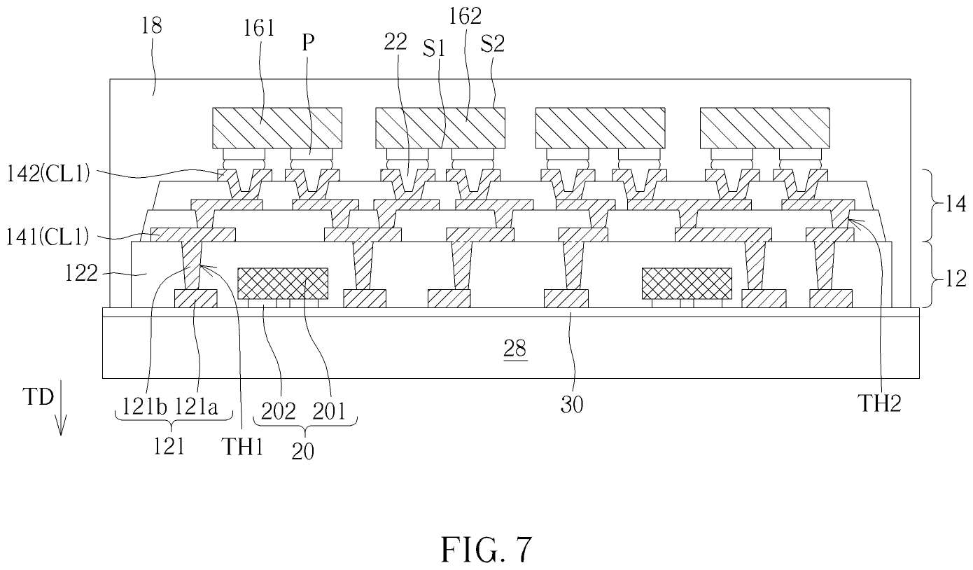

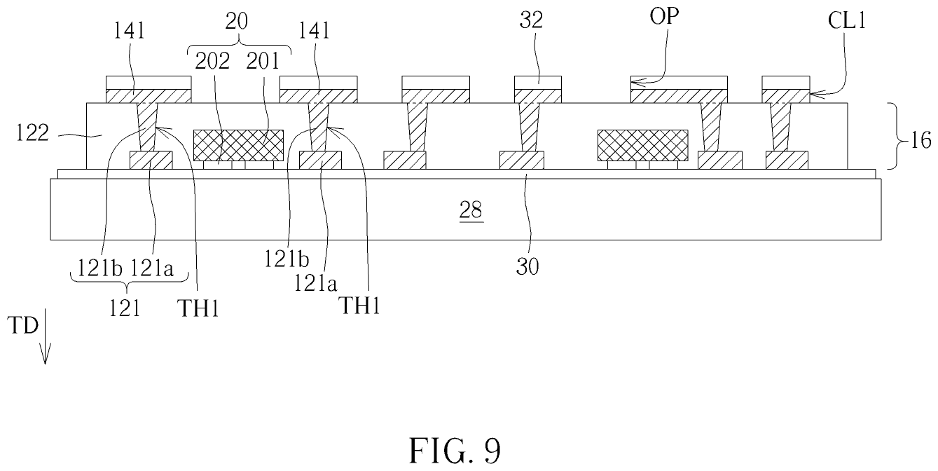

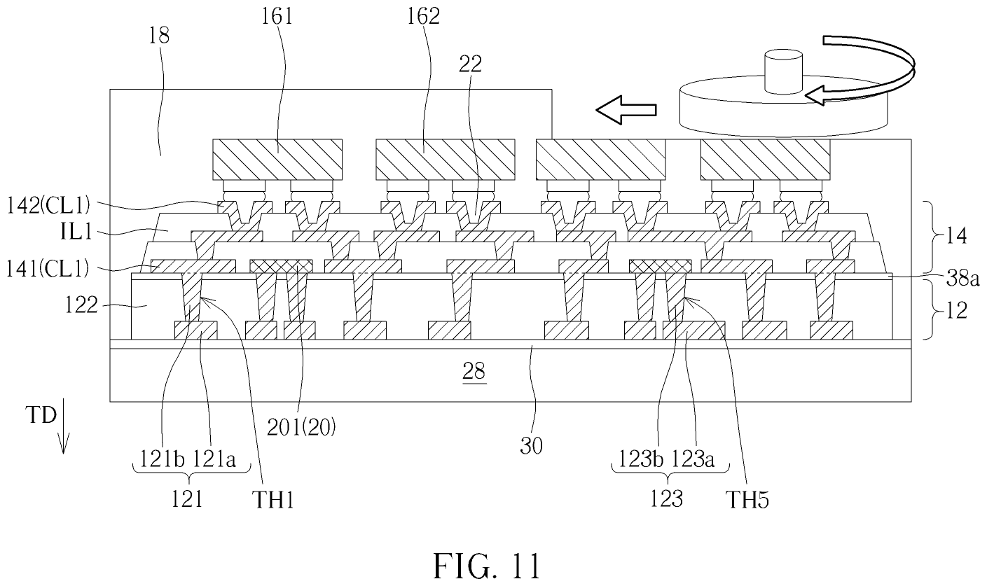

As shown in FIG. 2, the first redistribution structure 14 may include at least two conductive layers CL1 and at least one insulating layer IL1, and the conductive layers CL1 and the insulating layer IL1 may be alternately stacked on the base layer 12. A stacking direction of the conductive layers CL1 and the insulating layer IL1 may be, for example, a normal direction ND of a surface of the base layer 12 in the electronic device 1 facing the first redistribution structure 14, and the normal direction ND may be opposite to a top view direction of the electronic device 1 (e.g., opposite to a top view direction TD in FIG. 5, FIG. 7, FIG. 9 and FIG. 11), but not limited thereto. The insulating layer IL1 may have a through hole TH2, each conductive layer CL1 may include a trace 141, and the traces 141 of different conductive layers CL1 may be electrically connected to each other through the through hole TH2 to form a plurality of routes. For example, the redistribution structure redistributes the wires and/or increases the fan-out area of the wires, or the redistribution structure functions as a circuit structure such that at least two electronic units may be electrically connected to each other through the redistribution structure.

In this embodiment, the number of conductive layers CL1 and the number of insulating layers IL1 may be plural, but not limited thereto. The conductive layer CL1 closest to the base layer 12 may, for example, include at least one trace 141, and the trace 141 and at least a portion of the via structure 121 may include the same material. For example, the trace 141 and the at least a portion of the via structure 121 (e.g., the conductive pillar 121b) may be formed of the same conductive layer CL1, but not limited thereto.

In the first redistribution structure 14 of this embodiment, the conductive layer CL1 farthest from the base layer 12 may include a plurality of connecting pads 142 used for being electrically connected with the first electronic unit 161 and the second electronic unit 162. As shown in an upper left enlarged portion of FIG. 2, the conductive layer CL1 may include, for example, a seed layer SL and a metal layer ML stacked in sequence. Although FIG. 2 illustrates that the connecting pad 142 may include a seed layer SL and a metal layer ML, the trace 141 may also include the seed layer SL and the metal layer ML. The seed layer SL may provide electrical conductivity or improve adhesion between the layers. The seed layer SL may, for example, include titanium, titanium nitride, copper, tantalum or other suitable materials, but not limited thereto. The metal layer ML may include, for example, copper, titanium, aluminum, molybdenum, nickel, an alloy of any of the above metals, or a combination of any two of the above metals, but not limited thereto. The connecting pad 142 may be, for example, an under bump metal (UBM). In FIG. 2, the connecting pad 142 may extend to be on an upper surface of the insulating layer IL1 outside the through hole TH2, but not limited thereto. In some embodiments, the connecting pad 142 may not extend to be outside the through hole TH2, such as the connecting pad 242 shown in FIG. 2, but not limited thereto. In FIG. 2, a width W4 of the seed layer SL is equal to a width W5 of the metal layer ML. In some embodiments, the width W4 of the seed layer SL is not equal to the width W5 of the metal layer ML, wherein the widths W4, W5 are measured along a direction perpendicular to the normal direction ND. For example, different widths W4, W5 of the seed layer SL and the metal layer may be selected considering different stress requirements, but not limited thereto.

As shown in FIG. 2, the electronic device 1 may further include at least one conductive pad 22 disposed between the first electronic unit 161 and the first redistribution structure 14, and the first electronic unit 161 may be electrically connected to the first redistribution structure 14 and the second electronic unit 162 through the conductive pad 22. In this embodiment, the number of the conductive pad 22 may be, for example, plural, and the pads P of the first electronic unit 161 and the pads P of the second electronic unit 162 may be bonded and electrically connected to the corresponding connecting pads 141 in the first redistribution structure 14 through the conductive pads 22. The conductive pad 22 may include, for example, a solder ball, a solder bump, tin, silver, nickel, gold or other conductive materials. For example, in a direction perpendicular to the top view direction, a diameter of the conductive pad 22 of the electronic device 1 may be greater than or equal to 40 μm and less than or equal to 200 μm.

The protecting layer 18 may be used to reduce influence of moisture on the first electronic unit 161 and the second electronic unit 162. In the embodiment of FIG. 2, the protecting layer 18 may be disposed on the first electronic unit 161 and the second electronic unit 162 and may be located between the first electronic unit 161 and the first redistribution structure 14 and between the second electronic unit 162 and the first redistribution structure 14, but not limited thereto. A material of the protecting layer 18 may include, for example, epoxy resin, EMC, polymer, other suitable packaging materials or any combination thereof, but not limited thereto. In some embodiments, the protecting layer 18 may extend to and contact a side surface of the first redistribution structure 14, but not limited thereto. In some embodiments, the protecting layer 18 may further extend to a side surface of the base layer 12 and contact it, but not limited thereto. In some embodiments, the protecting layer 18 may not be disposed on the first electronic unit 161 and the second electronic unit 162, so that the back surfaces S2 of the first electronic unit 161 and the second electronic unit 162 may be exposed (e.g., as shown in FIG. 10), so as to facilitate heat dissipation and/or perform specific functions, such as functions of emitting and/or receiving laser, light or electromagnetic waves, detecting radar waves or other suitable functions.

In some embodiments, the protecting layer 18 may include a plurality of second filling particles distributed therein, such that the protecting layer 18 may provide good protection to components surrounded by it or beneath it. The second filling particle may, for example, include silicon dioxide or other suitable material. A diameter of the second filling particle of the protecting layer 18 may be, for example, ranged from 25 μm to 30 μm (i.e., 25 μm the diameter of the second filling particle ≤30 μm), and/or a solid content of the protecting layer 18 may be, for example, ranged from 75% to 80% (i.e., 75%≤the solid content≤80%), so that the protecting layer 18 may have good rigidity to provide sufficient protection, but not limited thereto. The solid content of the protecting layer 18 may be, for example, a proportion of the second filling particles in the protecting layer 18.

As shown in FIG. 2, the electronic device 1 may optionally further include a second redistribution structure 24 disposed on a side of the base layer 12 opposite to the first redistribution structure 14, in which the first redistribution structure 14 is electrically connected to the second redistribution structure 24 through the via structure 121. The second redistribution structure 24 may, for example, include at least one conductive layer CL2 and at least one insulating layer IL2, and the conductive layer CL2 and the insulating layer IL2 may be alternately stacked on the base layer 12. In this embodiment, the number of conductive layers CL2 and the number of insulating layers IL2 may be plural, but not limited thereto. Each insulating layer IL2 may have a through hole TH3, and different conductive layers CL2 may be electrically connected to each other through the through hole TH3 to form a plurality of routes. The conductive layers CL2 located between adjacent insulating layers IL2 may include a plurality of traces 241, and the conductive layer CL2 of the second redistribution structure 24 farthest from the base layer 12 may include a plurality of connecting pads 242 used for being connected with other components (e.g., a circuit board). In FIG. 2, the connecting pads 242 may not extend to be outside the through hole TH3, but not limited thereto. In some embodiments, the connecting pads 242 may extend to be outside the through hole TH3 and on a lower surface of the insulating layer IL2, but not limited thereto. In some embodiments, in the top view of the electronic device 1, the connecting pads 242 may not overlap the sidewalls of the first electronic unit 161 and the sidewalls of the second electronic unit 162 to improve reliability of the electronic device 1. In some embodiments, the protecting layer 18 may further contact an upper surface of the second redistribution structure 24 facing the base layer 12.

As shown in FIG. 2, the electronic device 1 may further include a plurality of conductive pads 26 disposed on the connecting pads 242 of the second redistribution structure 24 and used for being bonded and electrically connected to other components. The conductive pads 26 may be the same as or similar to the conductive pads 22, so they are not described in detail herein. For example, in the direction perpendicular to the top view direction (opposite to the normal direction ND), a diameter of the conductive pad 26 may be greater than or equal to a diameter of the conductive pad 22, so that the conductive pad 26 may tolerate a large current or pass a reliability test (e.g., a drop test), but not limited thereto.

In this embodiment, the connecting component 20 may be electrically connected to the first redistribution structure 14 through the second redistribution structure 24, so that one of the pads P of the first electronic unit 161 and one of the pads P of the corresponding one of the second electronic units 162 may be electrically connected to the connecting component 20 through the first redistribution structure 14, the via structure 121 and the second redistribution structure 24, but not limited thereto. Another one of the pads P of the first electronic unit 161 and/or another one of the pads P of the second electronic unit 162 may be electrically connected to a ground signal. For example, at least one via structure 121 may be electrically connected to the ground signal, for example, to achieve an electrostatic protection effect.

In some embodiments, the insulating layers IL1 and the insulating layers IL2 may include resin, photosensitive polyimide (PSPI), PI, Ajinomoto build-up film (ABF) or other suitable insulating materials. The conductive layers CL2 may, for example, include the same material as the conductive layers CL1 and may include a seed layer SL and a metal layer ML, but not limited thereto. In some embodiments, a thickness of the insulating layer IL1 and a thickness of the insulating layer IL2 may be greater than or equal to 5 μm and less than or equal to 25 μm, but not limited thereto.

As shown in FIG. 1, the electronic device 1 may further include a plurality of alignment marks AM for aligning to a predetermined position when the electronic device 1 is bonded to other components. The alignment marks AM may be formed of, for example, any one of the conductive layers CL1 in the first redistribution structure 14 or any one of the conductive layers CL2 in the second redistribution structure 24 in FIG. 2, but not limited thereto.

Refer to FIG. 3, which schematically illustrates a cross-sectional view of the connecting component according to an embodiment of the present disclosure. As shown in FIG. 3, the connecting component 20 may include, for example, the IPD, and the connecting component 20 may include at least two conductive layer CL3 and at least one insulating layer DL, in which the conductive layers CL3 and the insulating layer DL may form at least one passive component. In this embodiment, the connecting component 20 may include a substrate 20a, a plurality of conductive layers CL3, and a plurality of insulating layers DL, and the conductive layers CL3 and the insulating layers DL may be alternately formed on the lower surface 20S1 of the substrate 20a. Each conductive layer CL3 may include at least one electrode E. The electrodes E of two of the conductive layers CL3 may be overlapped with each other in the normal direction ND perpendicular to the lower surface 20S1, such that the electrodes E and the insulating layer DL therebetween may form a capacitor, for example. Further, the insulating layers DL may have a plurality of through holes TH4, and via structures 20b may respectively be disposed in the through holes TH4, so that the electrodes E may be electrically connected to the conductive layer CL3 farthest from the substrate 20a through the via structures 20b, but not limited thereto. In this embodiment, the conductive layer CL3 farthest from the substrate 20a may include connecting pads 202 used for being electrically connected to the first redistribution structure 14 or the second redistribution structure 24. In one embodiment, the connecting component 20 may be disposed in the base layer 12 in a manner of the connecting pads 202 facing downward, as shown in FIG. 2, but not limited thereto. The layout structure of the conductive layers CL3 and the via structures 20b of the present disclosure is not limited to FIG. 3 and may be adjusted according to requirements. In some embodiments, the electrodes E may have a coil structure so as to form an inductor, but not limited thereto. In some embodiments, when the connecting component 20 may be directly formed on the base layer 12, as shown in FIG. 10 or FIG. 12, the connecting component 20 may not include the substrate 20a. In this case, the connecting component 20 may not include the connecting pads 202.

As shown in FIG. 3, in some embodiments, at least one corner of the upper surface 20S2 of the substrate 20a opposite to the lower surface 20S1 and adjacent to a side surface of the substrate 20a may have a rounded corner, so as to reduce crack caused by mismatch of coefficients of thermal expansion, but not limited thereto.

In some embodiments, the substrate 20a may be a supporting substrate, which for example includes a glass substrate, a plastic substrate or other suitable substrates. The plastic substrate includes, for example, PI or other suitable plastic materials. The conductive layers CL3 may include, for example, titanium, aluminum, molybdenum, copper or a stack or combination of at least two of the aforementioned. The insulating layers DL may include inorganic materials, such as silicon oxide, silicon nitride, silicon oxynitride or other suitable materials. According to some embodiments, a thickness of one of the insulating layers DL may be greater than or equal to 0.5 μm and less than or equal to 5 μm, but not limited thereto.

Refer to FIG. 4, which schematically illustrates a cross-sectional view of a connecting component according to another embodiment of the present disclosure. As shown in FIG. 4, the connecting component 20 may be, for example, a glass substrate integrated circuit. In this embodiment, the connecting component 20 may, for example, include a thin film transistor. Specifically, the connecting component 20 may include the substrate 20a, a plurality of conductive layers, a plurality of insulating layers and a semiconductor layer SEL, which form at least one transistor, especially form at least one thin film transistor. A single thin film transistor is as an example in FIG. 4, but not limited thereto. For example, the conductive layers may include a first conductive layer CL31, a second conductive layer CL32, and a third conductive layer CL33, and the insulating layers may include a first insulating layer DL1 and a second insulating layer DL2. The first conductive layer CL31 may include a gate G formed on the lower surface 20S1 of the substrate 20a, and the first insulating layer DL1 is disposed under the first conductive layer CL31 and serves as a gate insulating layer. The semiconductor layer SEL may be disposed under the first insulating layer DL1, and the second conductive layer CL32 may be disposed under the first insulating layer DL1 and the semiconductor layer SEL and include a source electrode S, a drain electrode D, and a connecting electrode CE that are separated from each other. The source S and the drain D are respectively disposed on two sides of the semiconductor layer SEL, and the connecting electrode CE is electrically connected to the gate G through a through hole of the first insulating layer DL1. The second insulating layer DL2 is disposed under the first insulating layer DL1, the second conductive layer CL32, and the semiconductor layer SEL, and the third conductive layer CL33 may include a plurality of connecting pads 202 respectively electrically connected to the source S, the drain D, and the connecting electrode CE through corresponding through holes of the second insulating layer DL2. In this embodiment, the semiconductor layer SEL may include amorphous silicon, polysilicon, or oxide semiconductor. The materials of the substrate 20a, the conductive layers and the insulating layers in FIG. 4 may refer to the description corresponding to FIG. 3 and are not described again. The substrate 20a of FIG. 4 may be the same as or similar to the substrate 20a of FIG. 3 and may optionally have at least one rounded corner, which will not be described again. In some embodiments, the connecting component 20 of FIG. 4 may not include the substrate 20a. In this case, the connecting component 20 may not include the connecting pads 202. The type of the thin film transistor in the present disclosure is not limited to FIG. 4, and the layout structure of the conductive layers may be adjusted according to the requirements.

A manufacturing method of the electronic device 1 of this embodiment is further described in detail below. Refer to FIG. 5 to FIG. 8 together with FIG. 2. FIG. 5 to FIG. 8 schematically illustrate cross-sectional structures in different steps of the manufacturing method of the electronic device according to the first embodiment of the present disclosure. The manufacturing method of the electronic device 1 of this embodiment may include the following steps. As shown in FIG. 5, firstly, a carrier 28 is provided to carry components formed in subsequent steps. The carrier 28 may, for example, include a rigid carrier. The rigid carrier may be, for example, a wafer, a panel, a composite substrate, a steel plate, a glass substrate, or other suitable carriers. A release layer 30 is then formed on the carrier 28, in which the release layer 30 may be used to separate the carrier 28 from the components formed on the release layer 30. The releasing method of the release layer 30 may, for example, include photo dissociation, laser lift off, thermal releasing or other suitable methods. A material of the carrier 28 may be adjusted according to the releasing method of the release layer 30. The release layer 30 may, for example, include polyethene (PE) release film, PET release film, oriented polypropylene (OPP) release film, composite release film (i.e., the release layer may be formed of two or more materials mentioned above that are combined), etc., but not limited thereto.

As shown in FIG. 6, the base layer 12 is then formed on the carrier 28. The step of forming the base layer 12 is further described below. As shown in FIG. 5, at least one connecting pad 121a may be formed on the release layer 30. In this embodiment, the number of the connecting pads 121a is plural, and the connecting pads 121a may be separated from each other, so that the connecting pads 121a may be used for being electrically connected to different signals, but not limited thereto. Specifically, the connecting pads 121a may be formed by, for example, forming a conductive layer (not shown) on an entire surface of the release layer 30 and then performing a patterning process, such as lithography and etching processes, on the conductive layer to form the connecting pads 121a. The connecting pads 121a of this embodiment may, for example, include a metal material, such as iron, aluminum, copper or composite metal materials, so as to help reduce the impedance of signal transmission.

After that, at least one connecting component 20 is formed on the release layer 30. In FIG. 5, the connecting component 20 uses a chip type as an example and may include a component body 201 and a plurality of connecting pads 202, but not limited thereto. The connecting pads 202 may be used to electrically connect components in the component body 201 to other components outside the connecting component 20. The connecting component 20 may be formed by, for example, disposing the connecting component 20 on the carrier 28 in a manner of the connecting pads 202 of the connecting component 20 facing downward, but not limited thereto. In addition, when viewed in the top view direction TD perpendicular to an upper surface of the carrier 28, the connecting component 20 and the connecting pads 121a may be staggered from each other.

After the connecting pads 121a and the connecting component 20 are formed, an insulating body 122 may be formed on the connecting pads 121a, the connecting component 20, and the carrier 28, and then, the insulating body 122 is patterned to form a plurality of through holes TH1 in the insulating body 122, in which the through holes TH1 respectively expose the corresponding connecting pads 121a. The step of forming the insulating body 122 may include, for example, a molding process or other suitable processes. In some embodiments, the through holes TH1 may, for example, be formed by at least two patterning processes and may have the stepped profile, so as to avoid incomplete removal caused by one patterning process.

As shown in FIG. 6, in this embodiment, after the insulating body 122 is formed, a photoresist pattern 32 having at least one opening OP may be formed on the insulating body 122, such that the opening OP corresponds to the through hole TH1. In this embodiment, the number of the opening OP is plural, but not limited thereto. The openings OP and the through holes TH1 may, for example, be disposed in a one-to-one or one-to-more correspondence. The step of forming the photoresist pattern 32 may include, for example, a photolithography process or other suitable processes. The photoresist pattern 32 may include, for example, dry film photoresist or other suitable photoresist materials. Subsequently, a plurality of conductive pillars 121b may be formed in the through holes TH1 of the insulating body 122 to form the base layer 12 and its via structures 121 and form the traces 141 on the insulating body 122. In this embodiment, the conductive pillars 121b and the traces 141 may be formed by the same process or formed of the same conductive layer CL1, but not limited thereto. In this embodiment, the conductive pillars 121b may fill up the corresponding through holes TH1, but not limited thereto.

The step of forming the conductive pillars 121b and the traces 141 in this embodiment may include the following steps. First, the seed layer SL may be formed on a surface of the insulating body 122 and the connecting pads 121a exposed by the through holes TH1. The step of forming the seed layer SL may include, for example, a deposition process, vapor process, sputtering process or other suitable processes. In some embodiments, the seed layer SL may be conformal to surfaces of the through hole TH1 and have the stepped profile, but not limited thereto. Subsequently, the photoresist pattern 32 may be formed on the seed layer SL outside the through holes TH1, and the opening OP expose a portion of the seed layer SL. The metal layer ML is then formed on the exposed seed layer SL. The step of forming the metal layer ML may include, for example, an electroplating process, a chemical plating (electroless plating) process or other suitable processes. Subsequently, the photoresist pattern 32 may be removed to expose a portion of the seed layer SL, and then, the exposed seed layer SL is removed to form the conductive pillars 121b and the traces 141.

The step of forming the conductive pillars 121b and the traces 141 in the present disclosure is not limited to the aforementioned. Refer to FIG. 9, which schematically illustrates the formation of the conductive pillars and the traces according to another embodiment of the present disclosure. As shown in FIG. 9, after the insulating body 122 is formed, the conductive layer CL1 may be directly formed on the insulating body 122 and in the through holes TH1, and then, the conductive layer CL1 is patterned. For example, a seed layer (e.g., the seed layer SL in FIG. 6) is conformally formed on the insulating body 122 and the connecting pads 121a in the through holes TH1, and then, the metal layer (e.g., the metal layer ML in FIG. 6) is formed on the seed layer. Subsequently, the photoresist pattern 32 is formed on the conductive layer CL1, and the conductive layer CL1 exposed by the openings OP of the photoresist pattern 32 is removed through an etching process, so as to form the conductive pillars 121b and the traces 141.

As shown in FIG. 7, after the base layer 12 is formed, the first redistribution structure 14 is formed on the base layer 12. The step of forming the first redistribution structure 14 may include, for example, alternately forming a plurality of insulating layers IL1 with the through holes TH2 and a plurality of other conductive layer CL1 after forming the above-mentioned conductive layer CL1, but not limited thereto. The number of the insulating layers IL1 and the number of other conductive layers CL1 may be adjusted according to the requirements. The step of forming the insulating layers IL1 may include, for example, a coating process combined with a lithography process, an exposure process combined with a development process, or a laser drilling process, etc., but not limited thereto. The step of forming other conductive layers CL1 may refer to the above-mentioned step of forming the conductive pillars 121b and traces 141 and is not described again herein.

Subsequently, the first electronic units 161 and the second electronic units 162 are disposed on the first redistribution structure 14. Specifically, the first electronic units 161 and the second electronic units 162 may be bonded and electrically connected to the connecting pads 142 of the first redistribution structure 14 through the conductive pads 22 in a manner of the pads P facing the first redistribution structure 14. The step of disposing the first electronic units 161 and the second electronic units 162 may include, for example, a flip-chip bonding process or other suitable processes. It should be noted that since the first electronic units 161 and the second electronic units 162 may be disposed after the base layer 12 and the first redistribution structure 14 are formed, there is no need to consider displacement compensation for the routes in the base layer 12 and the first redistribution structure 14 due to shifts of the first electronic unit 161 and the second electronic unit 162 during forming the base layer 12 and the first redistribution structure 14, thereby improving manufacturing efficiency and/or yield.

The protecting layer 18 may be then formed on the first redistribution structure 14, such that the protecting layer 18 may at least surround the first electronic units 161 and the second electronic units 162 to provide a protecting function. In this embodiment, the protecting layer 18 may be formed on surfaces of the first electronic units 161 and surfaces of the second electronic units 162 opposite to the first redistribution structure 14 (i.e., the back surfaces S2 of the first electronic units 161 and the back surfaces S2 of the second electronic units 162), but not limited thereto. Moreover, the protecting layer 18 may extend to a side surface of the first redistribution structure 14 and a side surface of the base layer 12, but not limited thereto.

In some embodiments, after the protecting layer 18 is formed, the protecting layer 18 may be optionally thinned to expose the back surfaces S2 of the first electronic units 161 and the back surface S2 of the second electronic unit 162, as shown in FIG. 11. The step of thinning the protecting layer 18 may include, for example, chemical mechanical polishing (CMP), mechanical grinding process or other suitable processes.

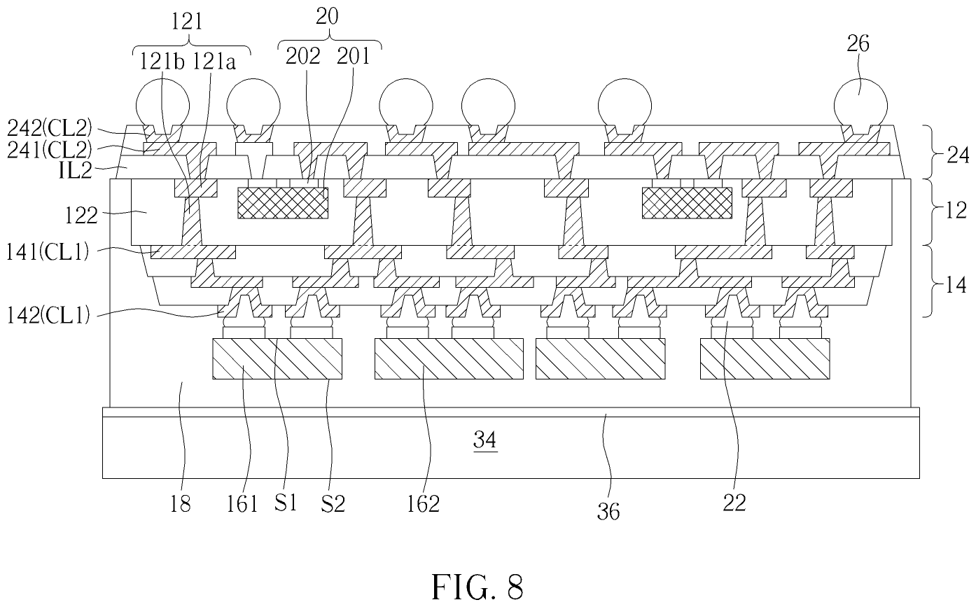

As shown in FIG. 8, after the protecting layer 18 is formed, the release layer 30 and the carrier 28 may be removed, and then, the base layer 12 formed with the first redistribution structure 14, the first electronic units 161, the second electronic units 162, and the protecting layer 18 is turned upside down to expose the connecting pads 121a and the connecting component 20. Furthermore, the base layer 12 may be disposed on another carrier 34 with the back surfaces S2 of the first electronic units 161 and the second electronic units 162 facing downward. Before the base layer 12 is disposed on the carrier 34, a release layer 36 may be formed on the carrier 34 for attaching and fixing the protecting layer 18 on the carrier 34, and after the electronic device 1 is formed, the release layer 36 may be used to separate the electronic device 1 from the carrier 34. The release layer 36 may, for example, be the same as or different from the release layer 30. Then, a second redistribution structure 24 may be formed on the side of the base layer 12 opposite to the first redistribution structure 14. The step of forming the second redistribution structure 24 may include alternately forming a plurality of insulating layers IL2 and a plurality of conductive layers CL2, but not limited thereto. Since the manner of forming the insulating layers IL2 and the conductive layers CL2 may be the same or similar to the manner of forming the insulating layers IL1 and the conductive layers CL1, they may refer to the contents mentioned above and will not be detailed again.

As shown in FIG. 8, after the second redistribution structure 24 is formed, a plurality of conductive pads 26 may be formed on the connecting pads 242 of the second redistribution structure 34, respectively. The conductive pads 26 may be formed, for example, by ball mounting, electroplating, printing or other suitable processes. As shown in FIG. 2, the carrier 34 and the release layer 36 are then removed, so as to form the electronic device 1 of this embodiment. In some embodiments, the step of forming the conductive pads 26 may be performed after removing the carrier 34 and the release layer 36, but not limited to this.

In some embodiments, after the carrier 34 and the release layer 36 are removed, a cutting process may be optionally performed, but not limited thereto. In this case, the protecting layer 18 of the electronic device 1 may not be disposed on the side surfaces of the base layer 12 and/or not disposed on the side surfaces of the first redistribution structure 14.

The electronic device and the manufacturing method thereof of the present disclosure are not limited to the above-mentioned embodiments and may have different embodiments. In order to simplify description, the different embodiments mentioned below will use the same reference numerals to denote the same components as the above-described embodiments. In order to clearly state the different embodiments, following description will state differences between embodiments, and the repeated parts are not detailed redundantly.

Refer to FIG. 10, which schematically illustrates a cross-sectional view of an electronic device according to a second embodiment of the present disclosure. As shown in FIG. 10, in the electronic device 2 of this embodiment, the connecting component 20 may be disposed in the first redistribution structure 14. In other words, the connecting component 20 may be surrounded by the first redistribution structure 14. For example, the connecting component 20 may be disposed on the base layer 12 and contact the insulating body 122, but not limited thereto. In this case, the base layer 12 may further include at least one via structure 123 that penetrates through the insulating body 122 and is used for electrically connecting the connecting component 20 to the second redistribution structure 24. The via structure 123 may include a connecting pad 123a and a conductive pillar 123b, and the conductive pillar 123b may be disposed between the connecting pad 123a and the first redistribution structure 14. In this embodiment, one of the first electronic units 161 and the corresponding second electronic unit 162 may be electrically connected to the connecting component 20 through the first redistribution structure 14, the via structure 121, the second redistribution structure 24, and the via structure 123, but not limited thereto. In some embodiments, the first electronic unit 161 and the corresponding second electronic unit 162 may be electrically connected to the connecting component 20 through the first redistribution structure 14.

In the embodiment of FIG. 10, the connecting component 20 may not include the connecting pads (e.g., the connecting pads 202 shown in FIG. 2, FIG. 3 or FIG. 4). In other words, the component body 201 of the connecting component 20 may be directly formed on the base layer 12, so as to reduce the thickness of the connecting component 20, but not limited thereto. For example, the component body 201 may refer to the component body 201 shown in FIG. 3 or FIG. 4 and will not be repeated herein. In some embodiments, the connecting component 20 of FIG. 10 may not include the substrate 20a shown in FIG. 3 or FIG. 4. In some embodiments, the connecting component 20 of FIG. 10 may be formed in the first redistribution structure 14. Alternatively, the connecting component 20 of FIG. 10 may include the connecting pads 202 shown in FIG. 2, FIG. 3 or FIG. 4, but not limited thereto.

In some embodiments, as shown in FIG. 10, the electronic device 2 may optionally include a first buffer layer 38a and/or a second buffer layer 38b to mitigate the warpage of the electronic device 2, in which the first buffer layer 38a may be disposed between the base layer 12 and the first redistribution structure 14, and the second buffer layer 38b may be disposed between the base layer 12 and the second redistribution structure 24. For example, the first buffer layer 38a may be formed on the insulating body 122 before the step of forming the through holes TH1, so that the through holes TH1 may penetrate through the first buffer layer 38a. The second buffer layer 38b may be formed on a side of the base layer 12 opposite to the first redistribution structure 14 before forming the second redistribution structure 24, such that the through holes (e.g., the through holes TH3 as shown in FIG. 2) of the second redistribution structure 24 may penetrate through the second buffer layer 38b, and the traces 241 may be electrically connected to the corresponding via structures 121.

As shown in FIG. 10, in this embodiment, the protecting layer 18 may not be disposed on the first electronic units 161 and the second electronic units 162, so that the back surfaces S2 of the first electronic units 161 and the second electronic units 162 may be exposed, which facilitates heat dissipation and/or performing specific functions, but not limited thereto. In some embodiments, the protecting layer 18 of FIG. 10 may be disposed on the back surfaces S2 of the first electronic unit 161 and the second electronic unit 162, but not limited thereto. Other parts of the electronic device 2 in FIG. 10 may refer to the above embodiment and will not be described redundantly.

Refer to FIG. 11 as well as FIG. 10. FIG. 11 schematically illustrates a manufacturing method of an electronic device according to a second embodiment of the present disclosure. As shown in FIG. 11, in the manufacturing method of the electronic device 2 of this embodiment, the step of forming the first redistribution structure 14 may include forming the connecting component 20 in the first redistribution structure 14. In this embodiment, the connecting component 20 may be formed on the base layer 12 after the base layer 12 is formed. For example, the step of forming the connecting pads 121a may include forming the connecting pads 123a on the carrier 28. The step of patterning the insulating body 122 may further include forming a plurality of through holes TH5 in the insulating body 122 to expose the connecting pads 123a respectively. The step of forming the conductive pillars 121b may include forming a plurality of conductive pillars 123b in the through holes TH5 respectively. After the conductive pillars 123b are formed, the connecting component 20 may be formed on the conductive pillars 123b and the insulating body 122. After that, the first redistribution structure 14 may be formed on the base layer 12. The manner of forming the insulating layers IL1 and the conductive layers CL1 of the first redistribution structure 14 may be the same as or similar to that of the above-mentioned embodiment, so it will not be detailed again.

As shown in FIG. 11, the protecting layer 18 may be optionally thinned to expose the back surfaces S2 of the first electronic units 161 and the second electronic units 162 between the step of forming the protecting layer 18 and the step of removing the carrier 28, but not limited thereto. In some embodiments, the protecting layer 18 of FIG. 11 may not be thinned. Other steps of the manufacturing method of the electronic device 2 in this embodiment may be the same as or similar to the above-mentioned embodiment, so they are not repeated here.

Refer to FIG. 12, which schematically illustrates a cross-sectional view of an electronic device according to a third embodiment of the present disclosure. As shown in FIG. 12, in the electronic device 3 of this embodiment, the connecting component 20 may be disposed in the second redistribution structure 24. In other words, the connecting component 20 may be surrounded by the second redistribution structure 24. For example, the connecting component 20 may be disposed on the side of the base layer 12 opposite to the first redistribution structure 14 and contact the base layer 12, but not limited thereto. In some embodiments, the connecting component 20 may not contact the base layer 12. The connecting component 20 may be the same as or similar to the connecting component 20 shown in FIG. 2, FIG. 3, FIG. 4 or FIG. 10 and may be referred to the contents mentioned above, so it will not be repeated. In some embodiments, as shown in FIG. 12, the electronic device 3 may further include at least one third electronic unit 163, and the pads P of the third electronic unit 163 may be on side surfaces of the main body of the third electronic unit 163. In some embodiments, a portion of the pads P of the third electronic unit 163 may be disposed between the main body of the third electronic unit 163 and the connecting pads 142, but not limited thereto. In some embodiments, the electronic device 3 may further include a buffer layer BL disposed on the first redistribution structure 14 and adjacent to the connecting pads 142. A thickness of the buffer layer BL may be greater than or equal to a thickness of the conductive layer CL1. One of the conductive pads 22 may be in contact with a side surface of the corresponding connecting pad 142. In other words, a portion of the conductive pad 22 may be disposed between the buffer layer BL and one of the connecting pads 142. A distance D1 between two adjacent connecting pads 142 may be less than or equal to one tenths of the width W1 of the first electronic device 161 or the width W2 of the second electronic device 162 and greater than or equal to 20 μm (i.e., 20 μm≤the distance D1≤(the width W1 or the width W2)/10). Since the adjacent connecting pads 142 have the distance D1 between them, the conductive pads 22 on the side surfaces of the adjacent connecting pads 142 would be prevented from being shorted. In some embodiments, as shown in FIG. 12, the electronic device 3 may further include a circuit board CB electrically connected with the conductive pads 26, wherein there is at least another electronic unit 164 disposed on the circuit board CB. In some embodiments, the pads P of the electronic unit 164 may be on side surfaces of a main body of the electronic unit 164, but not limited thereto. In some embodiments, a portion of the pads P of the electronic unit 164 may be disposed between the main body of the electronic unit 164 and the circuit board CB, but not limited thereto. In some embodiments, as shown in FIG. 12, the electronic device 3 may further include a filling layer FL disposed between the second redistribution structure 24 and the circuit board CB. The filling layer FL may be in contact with a portion of the protecting layer 18. In some embodiments, as shown in FIG. 12, a distance D3 between the third electronic unit 163 and the second electronic unit 162 is different from a distance D2 between the second electronic unit 162 and the first electronic unit 161. Materials of the buffer layer BL and the filling layer FL may include, for example, epoxy resin, EMC, polymer, other suitable packaging materials or any combination thereof, but not limited thereto. Other parts of the electronic device 3 in FIG. 12 may refer to the above-mentioned embodiments and will not be repeated. In some embodiments, as shown in FIG. 12, the via structure 121 may not include the connecting pads 121a, but the second redistribution structure 24 may include the connecting pads 243 disposed on a surface of the base layer 12 opposite to the first redistribution structure 14, in which the connecting pads 243 may be electrically connected to the corresponding via structures 121, respectively. For example, the via structures 121 may penetrate through the insulating body 122 and be formed of the conductive pillar 122, but not limited thereto.

In the manufacturing method of the electronic device 3 in this embodiment, the step of forming the second redistribution structure 24 may include forming the connecting component 20 in the second redistribution structure 24. For example, after the step of removing the carrier and the release layer (e.g., the carrier 28 and the release layer 30 shown in FIG. 7), the connecting component 20 may be formed on the side of the base layer 12 opposite to the first redistribution structure 14, and then, the second redistribution structure 24 may be formed, but not limited thereto.

As mentioned above, in the electronic device of the present disclosure, since the first electronic unit and the second electronic unit are surrounded by a protecting layer, the first electronic unit and the second electronic unit may be packaged in the same electronic device, thereby thinning or miniaturizing the electronic device. In addition, in the manufacturing method of the electronic device of the present disclosure, since the step of disposing the first electronic unit and the second electronic unit is performed after the base layer and the first redistribution structure are formed, there is no need to consider displacement compensation for the routes in the base layer and the first redistribution structure due to shifts of the first electronic unit and the second electronic unit, thereby improving the manufacturing efficiency and/or yield.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a base layer comprising at least one via structure;
a first redistribution structure disposed on the base layer;
a first electronic unit and a second electronic unit disposed on the first redistribution structure;
a protecting layer surrounding the first electronic unit, the second electronic unit and the base layer; and
a connecting component, wherein at least one of the first electronic unit and the second electronic unit is electrically connected to the connecting component through the first redistribution structure and the at least one via structure.

2. The electronic device as claimed in claim 1, further comprising at least one conductive pad disposed between the first electronic unit and the first redistribution structure, and the first electronic unit is electrically connected to the first redistribution structure and the second electronic unit through the at least one conductive pad.

3. The electronic device as claimed in claim 1, wherein the at least one via structure is electrically connected to a ground signal.

4. The electronic device as claimed in claim 3, further comprising a second redistribution structure disposed on a side of the base layer opposite to the first redistribution structure, wherein the first redistribution structure is electrically connected to the second redistribution structure through the at least one via structure.

5. The electronic device as claimed in claim 4, wherein the second redistribution structure surrounds the connecting component.

6. The electronic device as claimed in claim 4, wherein the connecting component is electrically connected to the first redistribution structure through the second redistribution structure.

7. The electronic device as claimed in claim 1, wherein the base layer surrounds the connecting component.

8. The electronic device as claimed in claim 1, wherein the first redistribution structure surrounds the connecting component.

9. The electronic device as claimed in claim 1, wherein the second electronic unit is the same as the first electronic unit.

10. The electronic device as claimed in claim 1, wherein the connecting component comprises at least two conductive layer and at least one insulating layer, and the at least two conductive layer and the at least one insulating layer form a passive component.

11. The electronic device as claimed in claim 1, the connecting component comprises a thin film transistor.

12. A manufacturing method of an electronic device, comprising:
forming a base layer on a carrier, wherein the base layer has at least one via structure;
forming a first redistribution structure on the base layer;
disposing a first electronic unit and a second electronic unit on the first redistribution structure;
forming a protecting layer on the first redistribution structure, wherein the protecting layer surrounds the first electronic unit and the second electronic unit; and
removing the carrier, wherein the manufacturing method further comprises forming a connecting component, and the first electronic unit and the second electronic unit are electrically connected to the connecting component through the first redistribution structure and the at least one via structure.

13. The manufacturing method of the electronic device as claimed in claim 12, wherein forming the base layer comprises forming an insulating body on the carrier and forming the at least one via structure in the insulating body, and the connecting component is disposed on the carrier before forming the insulating body.

14. The manufacturing method of the electronic device as claimed in claim 13, wherein forming the first redistribution structure comprises forming a trace, and at least a portion of the at least one via structure and the trace are formed of a conductive layer.

15. The manufacturing method of the electronic device as claimed in claim 14, wherein forming the trace comprises forming the conductive layer on the insulating body and patterning the conductive layer.

16. The manufacturing method of the electronic device as claimed in claim 14, wherein forming the first redistribution layer further comprises forming a photoresist pattern having at least one opening on the insulating body before forming the trace.

17. The manufacturing method of the electronic device as claimed in claim 12, further comprising thinning the protecting layer to expose the first electronic unit and the second electronic unit after forming the protecting layer.

18. The manufacturing method of the electronic device as claimed in claim 12, further comprising forming a second redistribution structure on another side of the base layer opposite to the first redistribution structure, wherein the first redistribution structure is electrically connected to the second redistribution structure through the at least one via structure.

19. The manufacturing method of the electronic device as claimed in claim 18, wherein forming the second redistribution structure comprises forming the connecting component in the second redistribution structure.

20. The manufacturing method of the electronic device as claimed in claim 12, wherein forming the first redistribution structure comprises forming the connecting component in the first redistribution structure.
